(19) United States
(12) Patent Application Publication
(10) Pub. No.: US 2003/0179053 A1
(43) Pub. Date: Sep. 25, 2003

(54) Filter device

(76) Inventors: Robert Aigner, Unterhaching (DE); Pasi Tikka, Helsinki (FI); Juha Sakariella, Halikko (FI)

Correspondence Address: LERNER AND GREENBERG, P.A., Post Office Box 2480, Hollywood, FL, 33022-2480, US

(21) Appl. No.: 10/417,486

(22) Filed: Apr. 17, 2003

Related U.S. Application Data
(63) Continuation of application No. PCT/EP01/03328, filed on Mar. 23, 2001.

(51) Int. Cl. H03H 9/54; H03H 9/64

(52) U.S. Cl. 333/189; 333/190; 333/191; 333/193

(57) ABSTRACT

The present invention provides a filter device constructed of a combined ladder and lattice filter topology. The filter device synergistically combines the good features of both types of filters. Using the filter device, an integrated unbalanced-to-balanced filter device can be realized. Accordingly, a substantial decrease in the number of components can be achieved. Furthermore, the filter device can be integrated with further components, preferably active RF-components, on a single chip.

### CROSS-REFERENCE TO RELATED APPLICATION

This application is a continuation of copending International Application No. PCT/EP01/03328, filed Mar. 23, 2001, which designated the United States and was not published in English.

### BACKGROUND OF THE INVENTION

### FIELD OF THE INVENTION

The present invention relates to filter devices. The present invention especially relates to acoustic wave filter devices, e.g. Surface Acoustic Wave (SAW) filter devices, and/or Bulk Acoustic Wave (BAW) filter devices.

The need for using miniature and high performance filters in wireless communication devices has led to the widespread use of Surface Acoustic Wave (SAW) filters. In addition to Surface Acoustic Wave (SAW) filters, Bulk Acoustic Wave (BAW) filters can also be used. Bulk Acoustic Wave (BAW) filters typically include several Bulk Acoustic Wave (BAW) resonators. In a Bulk Acoustic Wave (BAW) filter, acoustic waves propagate in a direction that is perpendicular to the filter's layer surfaces. In contrast, acoustic waves that propagate within a Surface Acoustic Wave (SAW) filter do so in a direction that is parallel to the layer surfaces of the filter.

It is known to fabricate monolithic filters that include at least a Bulk Acoustic Wave (BAW) resonator device (also known in the art as “Thin Film Bulk Acoustic Wave Resonators (FBARs)”). For example, Bulk Acoustic Wave (BAW) resonators typically include two electrodes and a single piezoelectric layer that is disposed between the two electrodes. One or more acoustic isolation layers may also be employed between the piezoelectric layer and a substrate of the respective devices.

Bulk Acoustic Wave (BAW) filters can be fabricated to include various known types of Bulk Acoustic Wave (BAW) resonators. These known types of Bulk Acoustic Wave (BAW) resonators include three basic portions. A first one of the portions, which is used to generate acoustic waves, includes an acoustically-active piezoelectric layer. This layer may include, for example, zinc-oxide (ZnO), aluminum nitride (AlN), zinc-sulfur (ZnS), or any other suitable piezoelectric material that can be fabricated as a thin film. A second one of the portions includes electrodes that are formed on opposite sides of the piezoelectric layer. A third portion of the Bulk Acoustic Wave (BAW) resonator includes a mechanism for acoustically isolating the substrate from vibrations produced by the piezoelectric layer. Bulk Acoustic Wave (BAW) resonators are typically fabricated on silicon, gallium arsenide, or glass substrates using thin film technology (e.g., sputtering, chemical vapor deposition, etc.). Bulk Acoustic Wave (BAW) resonators exhibit series and parallel resonances that are similar to those of, for example, crystal resonators. Resonant frequencies of Bulk Acoustic Wave (BAW) resonators can typically range from about 0.5 GH to 5 GHz, depending on the layer thicknesses of the devices.

FIG. 8 shows an example of an acoustic wave filter device used in a mobile application. Generally, an RF signal is input from an antenna 80 through a switch 81 and is guided to an amplifier 84 via an acoustic wave filter device 82, for example, a bulk acoustic wave filter device (BAW), having unbalanced terminals and a characteristic impedance of 50 Ω. In same cases the amplifier 84 is a low noise amplifier having balanced terminals. This amplifier often has a characteristic impedance of about 150-200 Ω.

For this reason a matching circuit for impedance conversion and an unbalanced-to-balanced transformer have been required for connection to the amplifier side. A unbalanced-to-balanced transformer circuit 83 (usually called a balun) has been used for that function. However, the use of a balun 83 considerably increases the number of parts and cost, especially since baluns 83 are usually discrete components that are not integrated with the rest of the filter system 82 or the amplifier 84. Accordingly, there is a demand to decrease the number of components and achieve an integrated unbalanced-to-balanced acoustic wave filter device.

### SUMMARY OF THE INVENTION

It is accordingly an object of the invention to a filter device which overcomes the above-mentioned disadvantages of the prior art apparatus of this general type.

With the foregoing and other objects in view there is provided, in accordance with the invention, a filter device including: a first filter unit including at least one series resonator and at least one shunt resonantor in a ladder configuration; and a second filter unit connected to the first filter unit by a resonator of the first filter unit. The first filter unit includes an unbalanced terminal. The second filter unit includes at least four resonators in a lattice configuration. The second filter unit includes two balanced terminals.

In accordance with an added feature of the invention, the filter device is an acoustic wave filter.

In accordance with an additional feature of the invention, there is provided, a plurality of surface acoustic wave resonators.

In accordance with another feature of the invention, there is provided, a plurality of bulk acoustic wave resonators.

In accordance with a further feature of the invention, the first filter unit includes an odd number of resonators.

In accordance with a further added feature of the invention, the first filter unit includes at least three resonators; and the at least one series resonator of the first filter unit and the at least one shunt resonator of the first filter unit are part of the at least three resonators.

In accordance with a further additional feature of the invention, the first filter unit includes at least five resonators; and the at least one series resonator of the first filter unit and the at least one shunt resonator of the first filter unit are part of the at least five resonators.

In accordance with another added feature of the invention, the at least one series resonator of the first filter unit, the at least one shunt resonator of the first filter unit, and the at least four resonators of the second filter unit are of the same type.

In accordance with another additional feature of the invention, the at least four resonators of the second filter unit include a plurality of series resonators; and the at least one series resonator in the first filter unit and the plurality of series resonators in the second filter unit exhibit substantially equal resonance frequencies.

In accordance with yet an added feature of the invention, the at least four resonators of the second filter unit include a plurality of shunt resonators; and the at least one shunt resonator in the first filter unit and the plurality of shunt resonators in the second filter unit exhibit substantially equal resonance frequencies.

In accordance with yet an additional feature of the invention, the filter device and a plurality of active RF-components are integrated on a single chip.

In accordance with yet another feature of the invention, the filter device and an amplifier are integrated on a single chip.

The present invention provides a filter device constructed of a combined ladder and lattice filter topology. The inventive filter device synergetically combines the good features of both types of filters. The first filter unit in ladder configuration has a finite stopband attenuation, while the second filter unit has, at least in theory, an infinite stopband attenuation far from the passband. The filter device basically has also an infinite stopband attenuation far from the passband.

Using the filter device, an integrated unbalanced-to-balanced filter device can be realized. Accordingly, a substancial, decrease in the number of components can be achieved. Furthermore, the filter device can be integrated with further components, preferably active RF-components, on a single chip.

According to a preferred embodiment, the filter device is an acoustic wave filter, especially, a Surface Acoustic Wave (SAW) filter including surface acoustic wave resonators, or even more preferred, a Bulk Acoustic Wave (BAW) filter including bulk acoustic wave resonators.

According to a further preferred embodiment, the first filter unit includes the same types of resonators as the second filter unit. Especially, the first and the second filter unit can be fabricated using only two types of resonators—series and shunt resonators. Thereby, it is preferred that the series resonators in the first filter unit and the series resonators in the second filter unit exhibit substantially equal resonance frequencies. Furthermore, it is preferred that the shunt resonators in the first filter unit and the shunt resonators in the second filter unit exhibit substantially equal resonance frequencies.

According to a further preferred embodiment, the first filter unit includes an odd number of resonators, preferably at least 3 or 5 resonators (t-topology or π-topology).

Other features which are considered as characteristic for the invention are set forth in the appended claims.

Although the invention is illustrated and described herein as embodied in a filter device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a cross-sectional view of an exemplary embodiment of a Bulk Acoustic Wave (BAW) resonator that includes an air gap;

FIG. 2 is a plan view of the Bulk Acoustic Wave (BAW) resonator shown in FIG. 1;

FIG. 3 is a cross-sectional view of an exemplary embodiment of a Bulk Acoustic Wave (BAW) resonator that includes an acoustic mirror;

FIG. 4 is a first embodiment of an inventive filter device;

FIG. 5 is a graph comparing different filter topologies;

FIG. 6 is a schematic of a further embodiment of the inventive filter device;

FIG. 7 is a schematic of a filter devices integrated with an a low noise amplifier (LNA) or a power amplifier on a single chip; and

FIG. 8 a schematic of an example of a surface acoustic wave filter device used in a mobile environment.

### DESCRIPTION OF THE PREFERRED EMBODIMENTS

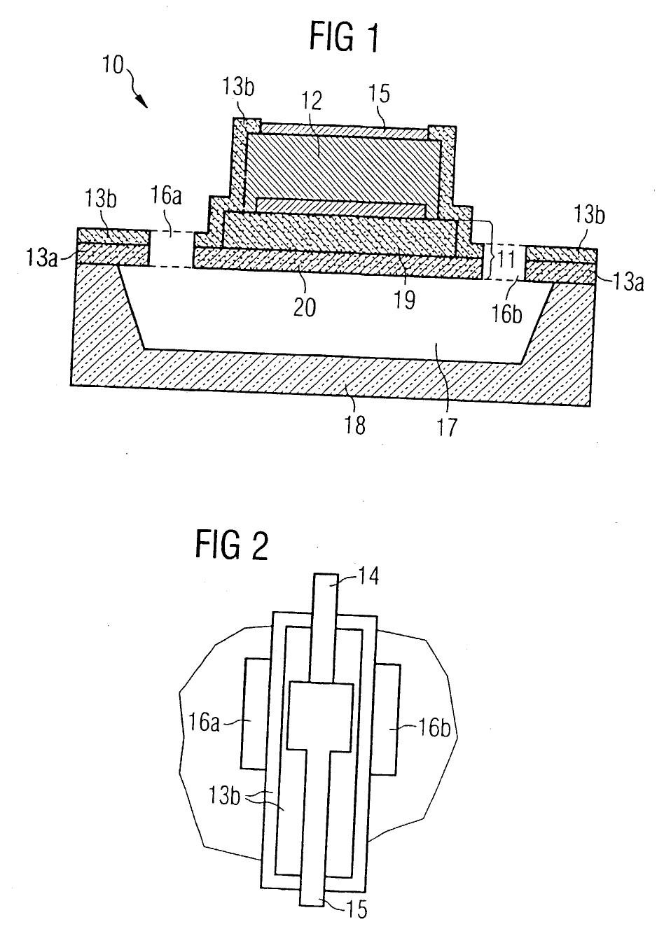

Referring now to the figures of the drawing in detail and first, particularly, to FIG. 1 thereof, there is shown a cross-sectional view of a Bulk Acoustic Wave (BAW) resonator 10 having a membrane 11 or bridge structure. FIG. 2 is a top view of the Bulk Acoustic Wave resonator 10. The Bulk Acoustic Wave (BAW) resonator 10 includes a piezoelectric layer 12, a first protective layer 13a, a second protective layer 13b, a first electrode 14, a second electrode 15, the membrane 11, etch windows 16a and 16b, an air gap 17, and a substrate 18. The piezoelectric layer 12 includes, for example, a piezoelectric material that can be fabricated as a thin film such as, for example, zinc-oxide (ZnO), or aluminum-nitride (AlN).

The membrane 11 includes two layers, namely, a top layer 19 and a bottom layer 20. The top layer 19 is made of, for example, poly-silicon or aluminum-nitride (AlN), and the bottom layer 20 is made of, for example, silicon-dioxide (SiO₂) or gallium arsenide (GaAs). The substrate 18 is included of a material such as, for example, silicon (Si), SiO₂, GaAs, or glass. Through the etch windows 16a and 16b, a portion of the substrate 18 is etched to form the air gap 17 after the membrane layers have been deposited over the substrate 18.

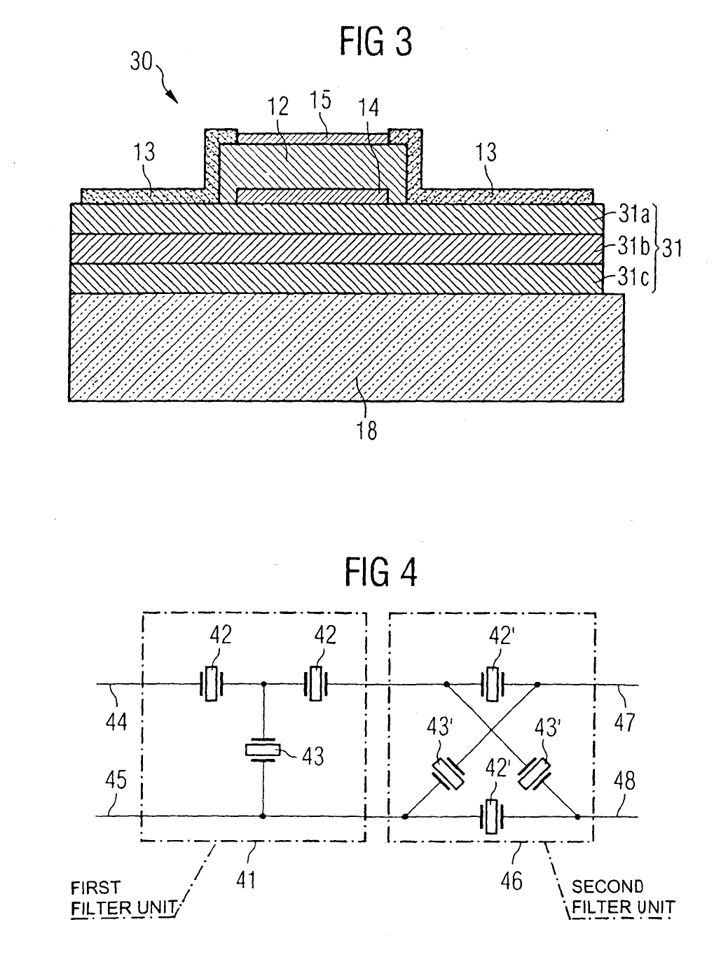

In FIG. 3, another Bulk Acoustic Wave (BAW) resonator 30 is shown. This resonator 30 has a similar structure as that of the Bulk Acoustic Wave (BAW) resonator 10 of FIG. 1, except that only a single protective layer 13 is provided, and the membrane 11 and the air gap 17 are replaced with an acoustic mirror 31 which acoustically isolates vibrations produced by the piezoelectric layer 12 from the substrate 18.

The acoustic mirror 31 includes a number of layers with alternating high and low acoustic impedances arrenged so that a reflection of the acoustic wave at the mirror-resonator interface is obtained. The acoustic mirror 31 shown in FIG. 3 includes three layers, namely a top layer 31a, a middle layer 31b, and a bottom layer 31c. Each layer 31a, 31b and 31c has a thickness that is, for example, approximately equal to one quarter wavelength. The top layer 31a and bottom layer 31c are made of materials having low acoustic impedances such as, for example, silicon (Si), poly-silicon, aluminum (Al), or a polymer. Furthermore, the middle layer 31b is made of a material having a high acoustic impedance such as, for example, gold (Au), molybdenum (Mo), or tungsten (W). The substrate 18 may be included of various high acoustic impedance materials or low acoustic impedance materials (e.g., Si, SiO₂, GaAs, glass, or a ceramic material)

FIG. 4 shows a first embodiment of an inventive filter device. The filter device shown in FIG. 4 includes two filters units that are directly connected via a series resonator of the first filter unit. The first filter unit 41 preferably includes an odd number of resonators, three in the present example, in a ladder configuration. The first filter unit 41 is a Bulk Acoustic Wave (BAW) filter including two types of bulk acoustic wave resonators—series resonators 42 and shunt resonators 43. Preferably, the first filter unit 41 is a Bulk Acoustic Wave (BAW) filter including bulk acoustic wave resonators such as those shown in FIGS. 1 to 3.

Furthermore, the first filter unit 41 includes one unbalanced terminal 44, to which, for example, the output signal of an antenna can be connected. In addition to the terminal 44, the first filter unit 41 includes the terminal 45, which is connected to ground in the present example.

The second filter unit 46 includes four resonators in a lattice configuration. Like the first filter unit 41, the second filter unit 46 is Bulk Acoustic Wave (BAW) filter including two types of bulk acoustic wave resonators—series resonators 42′ and shunt resonators 43′. Thereby, the series resonators 42 in the first filter unit 41 and the series resonators 42′ in the second filter unit 46 exhibit substantially equal resonance frequencies. The same applies to the shunt resonators 43 in the first filter unit 41 and the shunt resonators 43′ in the second filter unit 46 which also exhibit substantially equal resonance frequencies. Furthermore, the second filter unit 46 includes two balanced terminals 47 and 48, to which, for example, a low noise amplifier (LNA) can be connected.

The second filter unit 46 is connected to the first filter unit 41 via a series resonator 42 of the first filter unit 41, because otherwise an impedance mismatch between the two filter units would arise. Due to the fact that the first filter unit 41 ends with a series resonator and not with shunt resonator, the first filter unit 41 and the second filter unit 46 are well matched.

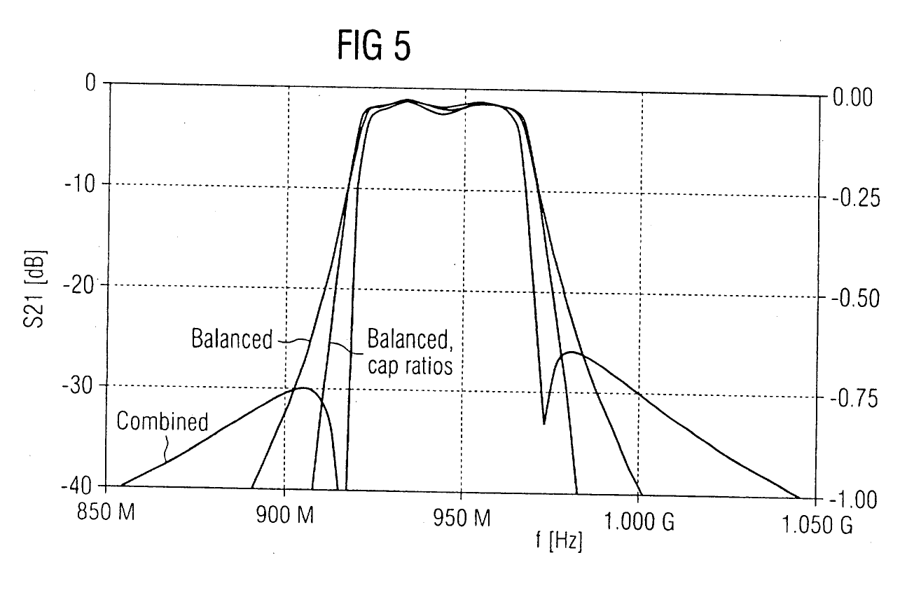

The inventive filter device exhibits an excellent response, especially when the node between the loads at the balanced side is not grounded (floating). Furthermore, the inventive filter device has a steeper transition from the passband to the stopband than a balanced filter or a balanced filter with different capacitance ratios. Accordingly, the inventive filter device exhibits a better selectivity than the other two filters. The results of a comparison are shown in FIG. 5.

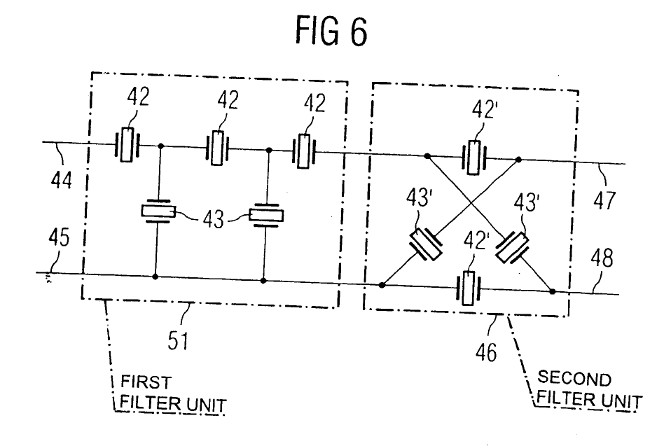

FIG. 6 shows a second embodiment of the inventive filter device. The filter device shown in FIG. 6 also includes two filter units that are directly connected via a series resonator of the first filter unit. The first filter unit 51 preferably includes an odd number of resonators, five in this example, in a ladder configuration. Again, the first filter unit 51 is Bulk Acoustic Wave (BAW) filter including two types of bulk acoustic wave resonators, series resonators 42 and shunt resonators 43. The second filter unit 46 is constructed similarly to that shown in FIG. 4.

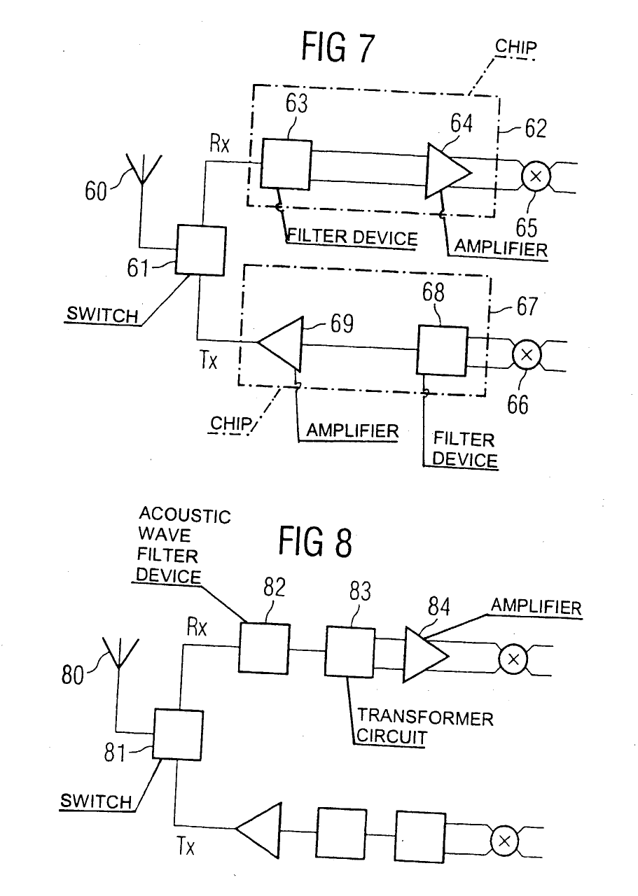

FIG. 7 shows a further embodiment of the present invention in which filter devices are integrated with a low noise amplifier (LNA) or a power amplifier on a single chip. FIG. 7 schematically shows the reception side (Rx) as well as the transmission side (Tx) of a mobile telecommunication device.

A signal received from the antenna 60 is guided via a switch 61 to the chip 62 which integrates a filter device 63 and a low noise amplifier (LNA) 64. The filter device 63 includes a first filter unit that has an odd number of resonators in a ladder configuration and a second filter unit that has at least four resonators in a lattice configuration. The filter device 63 filters the signal from the antenna 60 and performs a conversion from an unbalanced to a balanced signal. The resulting balanced signal is amplified by the low noise amplifier (LNA) 64 and is guided to a mixer 65.

A signal that is to be transmitted via the antenna 60 is produced by a mixer 66 and is guided to the chip 67, which integrates a filter device 68 and a power amplifier 69. The filter device 68 also includes a first filter unit that has an odd number of resonators in a ladder configuration and a second filter unit that has at least four resonators in a lattice configuration. The filter device 68 filters the signal from the mixer and performs a conversion from an balanced to an unbalanced signal. The resulting unbalanced signal is amplified by the power amplifier 69 and is guided to the antenna 60 via the switch 61.

Using the inventive filter device, an integrated unbalanced-to-balanced filter device can be realized. Accordingly, a substancial decrease in the number of components can be achieved. Furthermore, the inventive filter device can be integrated with further components, preferably a low noise amplifier (LNA), on a single chip. In addition, the inventive filter device preferably uses BAW filters, because BAW filters are more cost effective than existing SAW filters.

We claim:

1. A filter device, comprising:
a first filter unit including at least one series resonator and at least one shunt resonator in a ladder configuration; and
a second filter unit connected to said first filter unit by a resonator selected from a group consisting of said at least one series resonator of said first filter unit;
said first filter unit including an unbalanced terminal;
said second filter unit including at least four resonators in a lattice configuration; and
said second filter unit including two balanced terminals.

2. The filter device according to claim 1, wherein the filter device is an acoustic wave filter.

3. The filter device according to claim 1, further comprising a plurality of surface acoustic wave resonators.

4. The filter device according to claim 1, further comprising a plurality of bulk acoustic wave resonators.

5. The filter device according to claim 1, wherein said first filter unit includes an odd number of resonators.

6. The filter device according to claim 5, wherein: said first filter unit includes at least three resonators; and said at least one series resonator of said first filter unit and said at least one shunt resonator of said first filter unit are part of said at least three resonators.

7. The filter device according to claim 5, wherein: said first filter unit includes at least five resonators; and said at least one series resonator of said first filter unit and said at least one shunt resonator of said first filter unit are part of said at least five resonators.

8. The filter device according to claim 1, wherein said at least one series resonator of said first filter unit, said at least one shunt resonator of said first filter unit, and said at least four resonators of said second filter unit are of a same type.

9. The filter device according to claim 1, wherein:
said at least four resonators of said second filter unit include a plurality of series resonators; and
said at least one series resonator in said first filter unit and said plurality of series resonators in said second filter unit exhibit substantially equal resonance frequencies.

10. The filter device according to claim 1, wherein:
said at least four resonators of said second filter unit include a plurality of shunt resonators; and
said at least one shunt resonator in said first filter unit and said plurality of shunt resonators in said second filter unit exhibit substantially equal resonance frequencies.

11. The filter device according to claim 1, in combination with a plurality of active RF-components, wherein the filter device and the plurality of active RF-components are integrated on a single chip.

12. The filter device according to claim 1, in combination with an amplifier, wherein the filter device and the amplifier are integrated on a single chip.
